(19) United States
(12) Patent Application Publication
(10) Pub. No.: US 2002/0068398 A1
(43) Pub. Date: Jun. 6, 2002

(54) Method of manufacturing flash memory cell

(75) Inventors: Cha Deok Dong, Kyungki-Do (KR); Sang Wook Park, Seoul (KR)

Correspondence Address: MORGAN LEWIS & BOCKIUS LLP, 1111 PENNSYLVANIA AVENUE NW, WASHINGTON, DC, 20004, US

(73) Assignee: Hynix Semiconductor Inc.

(21) Appl. No.: 09/998,314

(22) Filed: Dec. 3, 2001

(30) Foreign Application Priority Data
Dec. 5, 2000 (KR) 00-73257

(51) Int. Cl. H01L 21/8238; H01L 21/336; H01L 21/3205; H01L 21/4763

(52) U.S. Cl. 438/201; 438/593; 438/257

(57) ABSTRACT

The present invention relates to a method of manufacturing a flash memory cell. The present invention forms a spacer at the sidewall of a floating gate pattern to increase the surface area of the floating gate, thus increasing a dielectric film. Therefore, the present invention can increase a gate coupling ratio. Also, the present invention can reduce the distance between the floating gates to prohibit a seam phenomenon generated upon deposition of a tungsten silicide film, thus reducing a word line resistance.

### BACKGROUND OF THE INVENTION

1. Field of the Invention

The invention relates generally to a method of manufacturing a flash memory cell, and more particularly to, a method of manufacturing a flash memory cell capable of reducing a step to prevent generation of a seam phenomenon of a tungsten silicide film subsequently formed by forming a spacer at the sidewall of a floating gate pattern.

2. Description of the Prior Art

A flash memory device has a gate in which a floating gate that is insulated by a tunnel oxide film, and a control gate that is insulated from the floating gate by a dielectric film are stacked at a given region on a semiconductor device. At this time, the floating gate is formed of a first polysilicon film so that it can overlap with a device isolation film at a given and the control gate is formed by a stack of a second polysilicon film and a tungsten silicide film.

However, the conventional floating gate is formed in a simple rectangular shape. Cell program and cell erasure operation are possible by an operating voltage further higher than the supply voltage of for example, about 5V, for example, 9V to the floating gate. Also, in order to secure a capacitance value of a dielectric film required for a gate coupling ratio of a certain value, there is a limit to reduce the thickness of the dielectric film. Furthermore, as a critical dimension between the floating gates overlapped with a device isolation film by a given portion is reduced since the design rule is reduced., there occurs a seam phenomenon by means of a poor step coverage characteristic of a tungsten silicide film when the second polysilicon film and the tungsten silicide film used as a control gate and a word line are formed. Due to this, as the sheet resistance of the word line increases, there is a limit that the integration level of a device is increased.

### SUMMARY OF THE INVENTION

It is therefore an object of the present invention to provide a method of manufacturing a flash memory cell capable of preventing a seam phenomenon of a tungsten silicide film by means of a step below a floating gate.

Another object of the present invention is to provide a method of manufacturing a flash memory cell capable of increasing a coupling ratio to increase the area of the floating gate, by forming a spacer at the sidewall of a floating gate.

In order to accomplish the above object, a method of manufacturing a flash memory cell according to the present invention, is characterized in that it forming a device isolation film at a given region on a semiconductor substrate and then sequentially forming a tunnel oxide film, a first polysilicon film and a buffer oxide film; etching given regions of the buffer oxide film, the first polysilicon film and the tunnel oxide film to form a floating gate pattern; forming a second polysilicon film on the entire surface and then performing a blanket etching process to form a spacer at the sidewall of the floating gate pattern; removing the buffer oxide film and then sequentially forming a dielectric film, a third polysilicon film, a tungsten silicide film and an antireflection film on the entire surface; patterning given regions from the anti-reflection film to the tunnel oxide film to form a gate structure in which a floating gate and a control gate are stacked; and forming source and drain regions at a given region of the semiconductor substrate.

### BRIEF DESCRIPTION OF THE DRAWINGS

The aforementioned aspects and other features of the present invention will be explained in the following description, taken in conjunction with the accompanying drawings, wherein:

FIG. 1 is a layout diagram of a flash memory cell array; and

FIGS. 2A through 2D are cross-sectional views of a devices for explaining a method of manufacturing a flash memory cell according to the present invention.

### DETAILED DESCRIPTION OF PREFERRED EMBODIMENTS

The present invention will be described in detail by way of a preferred embodiment with reference to accompanying drawings, in which like reference numerals are used to identify the same or similar parts.

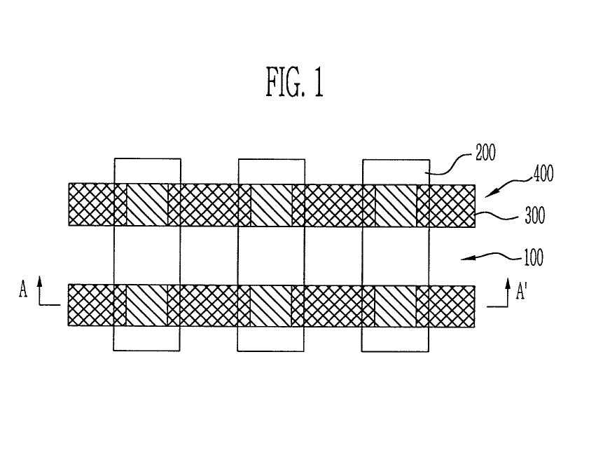

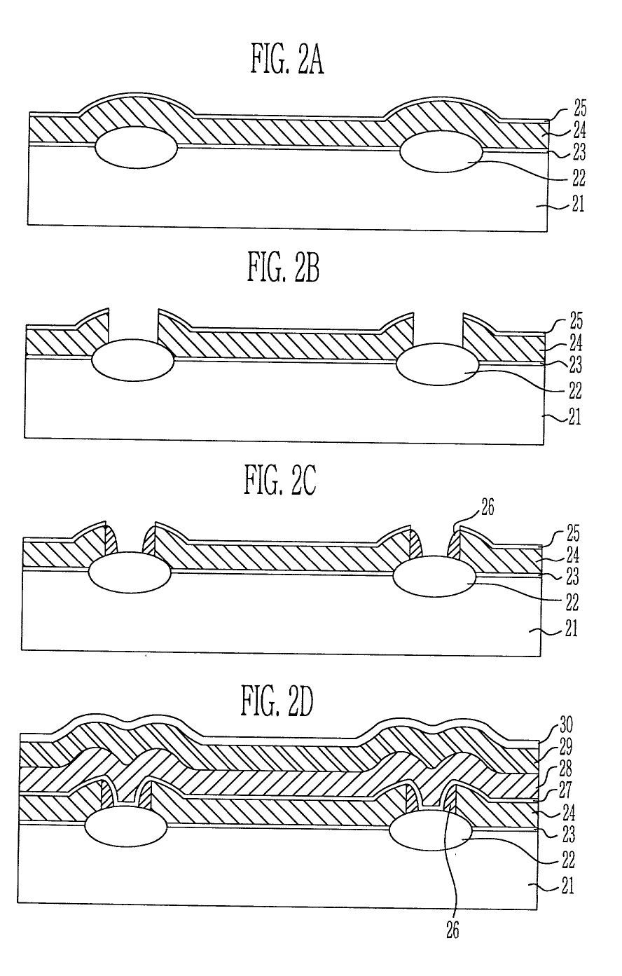

FIG. 1 is a layout diagram of a flash memory cell array, and FIGS. 2A through 2D are cross-sectional views of a devices for explaining a method of manufacturing a flash memory cell according to the present invention, which are taken along lines A-A′ in FIG. 1.

Referring not to FIG. 1 and FIG. 2(a), device isolation films 30, 22 are formed at a given region on semiconductor substrates 100 and 21 to define an active region and a field region. The device isolation films 200 and 22 are formed using a shallow trench isolation (STI) in a device of 0.28 μm class. After cleaning the surface of the semiconductor substrates 100 and 21 using dilute HF and SC-1 solution, a tunnel oxide film 23, a first polysilicon film 24 and a buffer oxide film 25 are sequentially formed on the entire surface. The tunnel oxide film 23 is formed in thickness of 50˜100 Å by performing wet oxidization using H₂ and O₂ at the temperature of 750˜800° C. and then performing a thermal process at the temperature of 800˜950° C. under N₂ gas atmosphere for 20˜30 minutes. Also, the first polysilicon film 24 is in thickness of 500˜2500 Å, which is a doped polysilicon film formed by means of LPCVD method using silicon source gas such as SiH₄ or Si₂H₆, etc. and PH₃ gas at the temperature of 550˜630° C. under the pressure of 0.1˜3.0 Torr. Meanwhile, the buffer oxide film 25 is formed in thickness of 100˜300 Å using one of a HTO oxide film sing SiH₄ gas and N₂0 gas, a DCS-HTO oxide film using SiH₂Cl₂ gas and N₂O gas, and a TEOS oxide film using TEOS(Si(OC₂H₅)₄) and O₂.

Referring now to FIG. 1 and FIG. 2B, the buffer oxide film 25, the first polysilicon film 24 and the tunnel oxide film 23 are patterned by means of lithography process and etching process using a floating gate as a mask to form a floating gate pattern. At this time, the floating gate pattern is formed to overlap with a portion of the device isolation films 200 and 22.

By reference to FIG. 2C, after forming a second polysilicon film on the entire surface, a blanket etching process is performed to form a spacer 26 at the sidewall of the floating gate pattern. As the spacer 26 is formed at the sidewall of the floating gate pattern, the surface area of the floating gate is increased and the distance between the floating gate patterns is reduced, thus reducing a step. At this time, the second polysilicon film is formed in thickness of 480˜500 Å using an amorphous silicon film at the temperature of 480˜550° C. under the pressure of 0.1˜3.0 Torr by means of LPCVD method using silicon source gases such as SiH₄ or Si₂H₆, etc. and PH₃ gas. At this time, in the blanket etching process for forming the spacer 26, the buffer oxide film 25 acts as an etch stop film and also acts to prevent damage of the first polysilicon film 24.

Referring now to FIG. 1 and FIG. 2D, the buffer oxide film 25 is completely removed by means of wet cleaning process using dilute HF solution or BOE. Then, a cleaning process is performed to remove a native oxide film and particles using dilute HF and SC-1 solution. Next, a dielectric film 27, a third polysilicon film 28, a tungsten silicide film 29 and an antireflection film 30 are sequentially formed on the entire surface. Patterning process is performed from the anti-reflection film 30 to the tunnel oxide film 23 by means of a lithography process using a control gate as a mask and an etching process, thus forming a gate structure in which the floating gate 300 and the control gate 400 are stacked. Thereafter, an impurity ion implantation process is performed to form source and drain on the semiconductor substrates 100 and 21.

The dielectric film 27 is so called an ONO film in which a lower oxide film, a nitride film and an upper oxide film are stacked. The lower oxide film and the upper oxide film are each is formed in thickness of 35˜100 Å using one of a thermal oxide film, a DCS(SiH₂Cl₂)-thermal oxide film and a CVD oxide film using TEOS. The thermal oxide film is formed by means of dry or wet oxidization method at the temperature of 750˜950° C. Also, and the DCS(SiH₂Cl₂)-thermal oxide film is formed using DCS(SiH₂Cl₂) and N₂O gas under the pressure of below 1 Torr and at the temperature of 750˜850° C. In addition, the nitride film is formed in thickness of 40˜100 Å by means of LPCVD method using NH₃ and DCS(SiH₂Cl₂) gas at the temperature of 600˜700° C. and under the pressure of below 1 Torr.

The third polysilicon film 28 is formed in thickness of 500˜1000 Å, which is formed by forming a doped polysilicon film by means of LPCVD method using silicon source gas and PH₃ gas at the temperature of 510˜550° C. and under the pressure of below 1 Torr and then in-situ depositing an undoped polysilicon film on the doped polysilicon film with supply of PH₃ gas stopped. At this time, it is recommended that the deposition ratio of the doped polysilicon film and the undoped polysilicon film is 5˜7:1. Meanwhile, the tungsten silicide film 29 is deposited by reaction of DCS(SiH₂Cl₂) or SiH₄ and WF₆ at the temperature of 300˜500° C. and its stoichiometry ratio (x) is controlled to be 2.3˜2.8.

As can be understood from the above description with the present invention, a dielectric film capacitance can be improved by forming a spacer at the sidewall of a floating gate to increase the surface area of the floating gate. Thus, the present invention can increase a gate coupling ratio. Also, the present invention can prohibit a seam phenomenon generated upon deposition of a tungsten silicide film since the distance between the floating gates can be reduced, thus reducing a word line resistance and improving an operating speed of the device.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed are:

1. A method of manufacturing a flash memory cell, comprising the steps of:
forming a device isolation film at a given region on a semiconductor substrate and then sequentially forming a tunnel oxide film, a first polysilicon film and a buffer oxide film;
etching given regions of said buffer oxide film, said first polysilicon film and said tunnel oxide film to form a floating gate pattern;
forming a second polysilicon film on the entire surface and then performing a blanket etching process to form a spacer at the sidewall of said floating gate pattern;
removing said buffer oxide film and then sequentially forming a dielectric film, a third polysilicon film, a tungsten silicide film and an antireflection film on the entire surface;
patterning given regions from said anti-reflection film to said tunnel oxide film to form a gate structure in which a floating gate and a control gate are stacked; and
forming source and drain regions at a given region of said semiconductor substrate.

2. The method of manufacturing a flash memory cell according to claim 1, wherein said floating gate pattern is formed to overlap with a given region of said device isolation film.

3. The method of manufacturing a flash memory cell according to claim 1, wherein said buffer oxide film is formed using one of a HTO oxide film sing SiH₄ gas and N₂O gas, a DCS-HTO oxide film using SiH₂Cl₂ gas and N₂O gas, and a TEOS oxide film using TEOS(Si(OC₂H₅)₄) and O₂.

4. The method of manufacturing a flash memory cell according to claim 1, wherein said buffer oxide film is formed in thickness of 100˜300 Å.

5. The method of manufacturing a flash memory cell according to claim 1, wherein said second polysilicon film is an amorphous silicon film.

6. The method of manufacturing a flash memory cell according to claim 5, wherein said amorphous silicon film is formed at the temperature of 480˜550° C. under the pressure of 0.1˜3.0 Torr by means of LPCVD method using silicon source gases such as SiH₄ or Si₂H₆, etc. and PH₃ gas.

7. The method of manufacturing a flash memory cell according to claim 1, wherein said second polysilicon film is formed in thickness of 480˜500 Å.
